(19) United States
(12) Patent Application Publication
(10) Pub. No.: US 2025/0087503 A1
(43) Pub. Date: Mar. 13, 2025

(54) SEMICONDUCTOR PACKAGE CUTTING SYSTEM AND METHOD

(71) Applicant: SEMES CO., LTD., Cheonan-si (KR)

(72) Inventors: Changhoon OK, Cheonan-si (KR); Jae Gyeong LEE, Cheonan-si (KR); Jinsoo KIM, Cheonan-si (KR)

(73) Assignee: SEMES CO., LTD., Cheonan-si (KR)

(21) Appl. No.: 18/824,705

(22) Filed: Sep. 4, 2024

(30) Foreign Application Priority Data
Sep. 7, 2023 (KR) 10-2023-0118946

(51) Int. Cl. H01L 21/67; H01L 21/677; H01L 21/78

(52) U.S. Cl. CPC H01L 21/67092; H01L 21/67034; H01L 21/67271; H01L 21/67721; H01L 21/67769; H01L 21/78

(57) ABSTRACT

Provided is a semiconductor package cutting system including a cutting device for partial-cutting at least a portion of a strip including a plurality of semiconductor packages, an inspection device mounted at a side of the cutting device to supply a first strip to be cut to the cutting device and to receive and inspect a second strip cut by the cutting device, and a storage device mounted at a side of the inspection device to supply the first strip stored therein, to the inspection device and to receive and store the second strip inspected by the inspection device, wherein the inspection device includes an inspection table for placing the second strip thereon and moving the second strip along a first direction.

### CROSS-REFERENCE TO RELATED PATENT APPLICATION

This application claims the benefit of Korean Patent Application No. 10-2023-0118946, filed on Sep. 7, 2023, in the Korean Intellectual Property Office, the disclosure of which is incorporated herein in its entirety by reference.

### BACKGROUND OF THE INVENTION

### 1. Field of the Invention

The present invention relates to a semiconductor package cutting system and method and, more particularly, to a semiconductor package cutting system and method capable of partial-cutting portions of semiconductor packages disposed on a strip, in a semiconductor device manufacturing process.

### 2. Description of the Related Art

In general, semiconductor devices may be formed on a silicon wafer used as a semiconductor substrate by repeatedly performing a series of manufacturing processes, and the semiconductor devices formed as described above may be produced as a semiconductor strip including a plurality of semiconductor packages through dicing, die bonding, and molding processes.

The semiconductor strip may be individualized into a plurality of semiconductor packages and then the semiconductor packages may be sorted into defective or non-defective products through a sawing and sorting process. For example, a sawing and sorting apparatus may include a cutting device for loading a semiconductor strip on a chuck table and then individualizing the semiconductor strip into a plurality of semiconductor packages by using a cutting blade, and an inspection device for cleaning and drying the individualized semiconductor packages, inspecting the semiconductor packages by using an inspection camera, and then sorting and unloading the semiconductor packages based on the inspection results.

Currently, as demands for small semiconductors are increased due to the rapid growth of the mobility industry, demands for a partial-cutting process capable of increasing wettability by cutting portions of the semiconductor packages before the sawing and sorting process are also increasing.

Although the above-described partial-cutting process has been performed by modifying an existing sawing and sorting apparatus, because an inspection device of the existing sawing and sorting apparatus is used, an additional storage unit is required to store partial-cut semiconductor strips, and thus the cost for the partial-cutting process and the footprint of the entire equipment are increased.

### SUMMARY OF THE INVENTION

The present invention provides a semiconductor package cutting system and method capable of performing a partial-cutting process by self-loading and unloading materials without an additional storage unit. However, the above description is an example, and the scope of the present invention is not limited thereto.

According to an aspect of the present invention, there is provided a semiconductor package cutting system including a cutting device for partial-cutting at least a portion of a strip including a plurality of semiconductor packages, an inspection device mounted at a side of the cutting device to supply a first strip to be cut to the cutting device and to receive and inspect a second strip cut by the cutting device, and a storage device mounted at a side of the inspection device to supply the first strip stored therein, to the inspection device and to receive and store the second strip inspected by the inspection device, wherein the inspection device includes an inspection table for placing the second strip thereon and moving the second strip along a first direction.

The inspection device may further include a vision unit mounted on a path of the inspection table to inspect a cut depth of the second strip, and rails extending in a second direction to place the first or second strip thereon.

The inspection device may further include a first gate provided at a side so as to be connected to the storage device, and a second gate provided at another side so as to be connected to the cutting device.

The first and second gates may be positioned to face each other, and the rails may be mounted between the first and second gates.

The storage device may store the first or second strip in a direction corresponding to a direction in which the rails extend.

The inspection device may include a plurality of inspection tables to sequentially inspect a plurality of second strips in the inspection device.

The cutting device may include a chuck table for fixing the first or second strip, a cutting unit including a replaceable blade to partial-cut at least a portion of the first strip fixed to the chuck table, and a cleaning unit for cleaning a surface or another surface of the cut second strip.

The cutting device may further include a strip picker for moving the strip positioned on one of the chuck table, the cutting unit, the cleaning unit, and the rails to another.

The strip picker may be movable back and forth in the second direction at a position corresponding to the rails.

According to another aspect of the present invention, there is provided a semiconductor package cutting method including (a) moving a strip supplied from a storage device and placed on rails of an inspection device, to a cutting device by moving a strip picker of the cutting device, (b) partial-cutting at least a portion of the strip by using the cutting device, (c) moving the cut strip to the inspection device and inspecting a cut depth, and (d) moving and storing the inspected strip to and in the storage device.

### BRIEF DESCRIPTION OF THE DRAWINGS

The above and other features and advantages of the present invention will become more apparent by describing in detail embodiments thereof with reference to the attached drawings in which:

FIG. 1 is a top view of a semiconductor package cutting system according to an embodiment of the present invention;

FIG. 2 is a top view of an inspection device of the semiconductor package cutting system according to an embodiment of the present invention;

FIG. 3 is a flowchart of a semiconductor package cutting method according to an embodiment of the present invention;

FIG. 4 is a cross-sectional view of a semiconductor package which is not partial-cut; and

FIG. 5 is a cross-sectional view of a semiconductor package which is partial-cut based on a semiconductor package cutting system and method according to embodiments of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

In the following description, a first direction refers to the y-axis direction in the drawings, a second direction refers to the x-axis direction, and a third direction refers to a direction perpendicular to the x-axis and y-axis directions. Further, in relation to strips described herein, for convenience and clarity of explanation, a strip before being cut is referred to as a first strip and a strip after being cut is referred to as a second strip, and the first and second strips are not different strips.

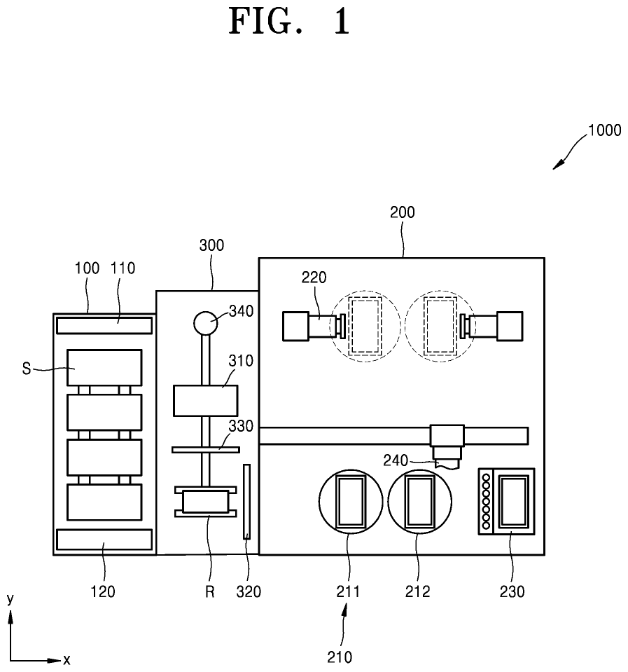

FIG. 1 is a top view of a semiconductor package cutting system 1000 according to an embodiment of the present invention. As shown in FIG. 1, the semiconductor package cutting system 1000 may include a storage device 100 for supplying and storing a strip S, a cutting device 200 for partial-cutting portions of semiconductor packages mounted on the strip S, and an inspection device 300 for inspecting the cut strip S.

Specifically, a plurality of first strips which are not cut may be stored in the storage device 100. The first strip may be transferred by an elevator 110 to a position accessible to the inspection device 300, and then transferred by a pusher 120 onto rails R mounted on the inspection device 300.

The cutting device 200 may include a chuck table 210 for supporting and fixing the first strip, a cutting unit 220 for partial-cutting portions of semiconductor packages on the first strip fixed to the chuck table 210, and a cleaning unit 230 for cleaning and drying a second strip which is cut.

Specifically, the cutting unit 220 may include a circular blade for partial-cutting at least portions of a plurality of semiconductor packages disposed on the strip. For example, the circular blade may be moved in the first direction, and the first strip fixed onto the chuck table 210 may be partial-cut (or half-cut) while the chuck table 210 is being moved in a second direction. The cleaning unit 230 may clean the second strip by using a brush or a cleaning solution to remove particles or foreign substances produced during the cutting process.

The cutting device 200 may further include a strip picker 240 for moving the strip positioned on one of the rails R, the chuck table 210, the cutting unit 220, the cleaning unit 230, and an inspection table 310 to another so as to perform a plurality of processes on the first strip.

Specifically, the strip picker 240 may move the first strip placed on the rails R to the chuck table 210, move the second strip cut on the chuck table 210 to the cleaning unit 230, and move the second strip cleaned by the cleaning unit 230 to the inspection table 310.

The strip picker 240 may move back and forth along the second direction, and the chuck table 210 and the cleaning unit 230 may be disposed along the second direction.

Therefore, the first strip brought onto the rails R by the pusher 120 of the storage device 100 may be transferred to the chuck table 210 by the strip picker 240, and the second strip partial-cut on the chuck table 210 by the cutting unit 220 may be transferred to the cleaning unit 230 and then transferred to the rails R of the inspection device 300 after being cleaned.

The inspection device 300 may include the inspection table 310 for placing the second strip thereon and being movable back and forth in the first direction. Therefore, the second strip placed on the rails R may be placed on the inspection table 310 by the strip picker 240 and moved to a vision unit 340.

The inspection device 300 may further include first and second drying units 320 and 330 for drying a surface and another surface of the second strip, and the vision unit 340 for inspecting a cut depth of the second strip.

In this case, the first drying unit 320 may be mounted on a path along which the second strip is transferred by the strip picker 240, to dry the surface of the second strip, and the second drying unit 330 may be mounted on a path along which the second strip is transferred to the vision unit 340 by the inspection table 310, to dry the other surface of the second strip. Alternatively, the first drying unit 320 may dry the other surface of the second strip and the second drying unit 330 may dry the surface of the second strip.

A plurality of second strips which are cut and inspected may be stored in the storage device 100. The second strip may be transferred from the rails R mounted on the inspection device 300 into the storage device 100 by the pusher 120, and then transferred to a storage position by the elevator 110. The pusher 120 may be a type of pusher block capable of pushing the second strip from the rails R into the storage device 100, or be a type of gripper or strip picker capable of bringing the second strip placed on the rails R, into the storage device 100 by gripping the second strip.

In this case, the inspection device 300 of the semiconductor package cutting system 1000 according to an embodiment of the present invention may further include a first gate G1 provided at a side so as to be connected to the storage device 100, and a second gate G2 provided at another side so as to be connected to the cutting device 200.

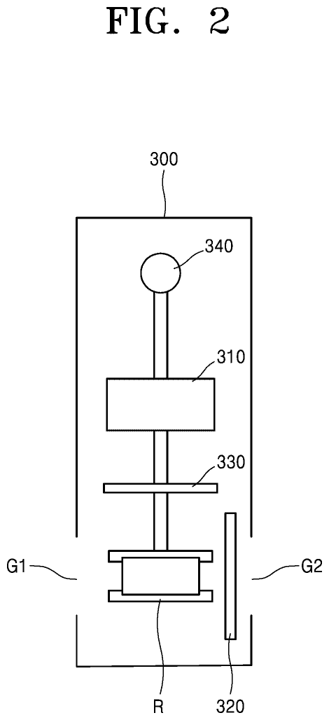

Specifically, as shown in FIG. 2, the first and second gates G1 and G2 may be positioned to face each other, and the rails R may be mounted between the first and second gates G1 and G2.

Therefore, the first strip may be brought onto the rails R through the first gate G1 by the pusher 120 of the storage device 100, the first strip placed on the rails R may be moved to the chuck table 210 through the second gate G2 by the strip picker 240, and the second strip after being cleaned may be transferred back to the rails R through the second gate G2 by the strip picker 240.

Based on the above-described disposition of the first and second gates G1 and G2, the second strip placed on the rails R may be moved to the storage device 100 by the strip picker 240, and the strips may be moved without additionally using the pusher 120.

Although not shown in the drawings, to increase the efficiency of transfer in consideration of paths of strips, a plurality of inspection tables may be included. Therefore, interference between the first strip being supplied to the cutting device 200 and the second strip being brought to the storage device 100 may be prevented and the efficiency of process may be increased.

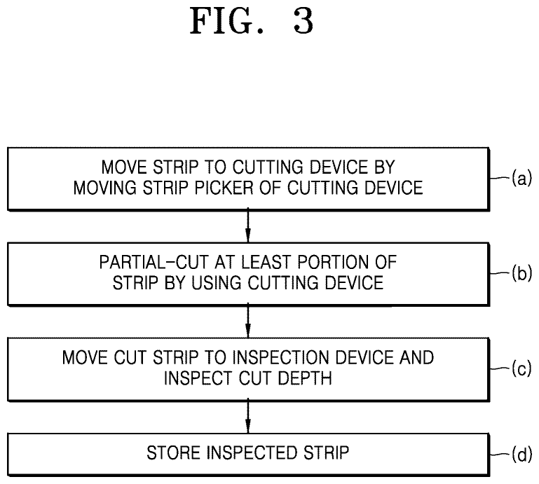

FIG. 3 is a flowchart of a semiconductor package cutting method according to an embodiment of the present invention. As shown in FIG. 3, the semiconductor package cutting method according to an embodiment of the present invention may include (a) moving a strip supplied from a storage device and placed on rails of an inspection device, to a cutting device by moving a strip picker of the cutting device, (b) partial-cutting at least a portion of the strip by using the cutting device, (c) moving the cut strip to the inspection device and inspecting a cut depth, and (d) moving and storing the inspected strip to and in the storage device.

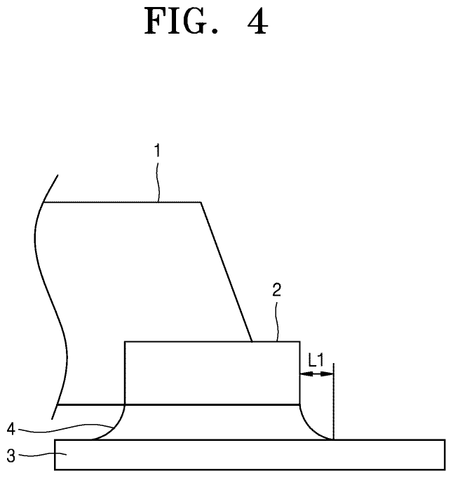

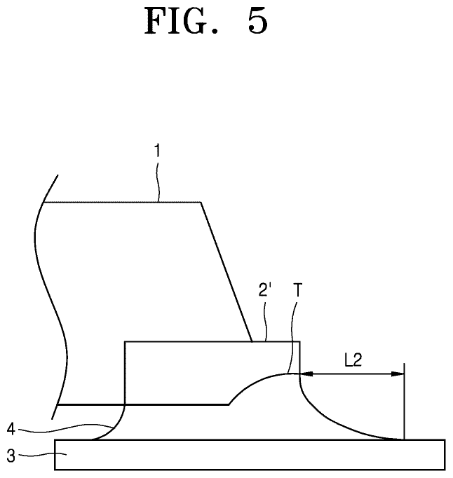

In this case, step (b) for partial-cutting at least a portion of the strip may include partial-cutting a portion of a terminal 2 of a semiconductor package 1 disposed on the strip, as shown in FIGS. 4 and 5.

FIG. 4 shows a general semiconductor package which is not partial-cut. Initially, as shown in FIG. 4, when the semiconductor package 1 is mounted on a substrate 3 through a reflow process of solder 4, the solder 4 exhibits a wetting shape having a first length L1.

Comparatively, as shown in FIG. 5, when a cutout T is formed by partial-cutting a portion of the terminal 2 of the semiconductor package 1 based on the semiconductor package cutting system and method according to embodiments of the present invention, the solder 4 exhibits a wetting shape having a second length L2 greater than the first length L1, which means that wettability is improved.

Consequently, based on the semiconductor package cutting system and method according to embodiments of the present invention, footprint may be reduced because strips are self-loadable and unloadable using one storage device without an additional storage unit, space may be efficiently used because the disposition of the storage device is changeable depending on an installation space of the entire system, an existing sawing and sorting apparatus may be used as a cutting device of the present invention by merely replacing a blade thereof, and transition to a subsequent process may be easily enabled by docking additional equipment at the rear of the storage device.

According to the afore-described embodiments of the present invention, footprint may be reduced because strips are self-loadable and unloadable without an additional storage unit, space may be efficiently used because the disposition of a storage device is changeable depending on an installation space of the entire system, and versatility may be achieved because a cutting device is usable as an existing sawing and sorting apparatus by merely replacing a blade thereof. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A semiconductor package cutting system comprising:
a cutting device for partial-cutting at least a portion of a strip comprising a plurality of semiconductor packages;
an inspection device mounted at a side of the cutting device to supply a first strip to be cut to the cutting device and to receive and inspect a second strip cut by the cutting device; and
a storage device mounted at a side of the inspection device to supply the first strip stored therein, to the inspection device and to receive and store the second strip inspected by the inspection device,
wherein the inspection device comprises an inspection table for placing the second strip thereon and moving the second strip along a first direction.

2. The semiconductor package cutting system of claim 1, wherein the inspection device further comprises:
a vision unit mounted on a path of the inspection table to inspect a cut depth of the second strip; and
rails extending in a second direction to place the first or second strip thereon.

3. The semiconductor package cutting system of claim 2, wherein the inspection device further comprises:
a first gate provided at a side so as to be connected to the storage device; and
a second gate provided at another side so as to be connected to the cutting device.

4. The semiconductor package cutting system of claim 3, wherein the first and second gates are positioned to face each other, and
wherein the rails are mounted between the first and second gates.

5. The semiconductor package cutting system of claim 2, wherein the storage device stores the first or second strip in a direction corresponding to a direction in which the rails extend.

6. The semiconductor package cutting system of claim 1, wherein the inspection device comprises a plurality of inspection tables to sequentially inspect a plurality of second strips in the inspection device.

7. The semiconductor package cutting system of claim 2, wherein the cutting device comprises:
a chuck table for fixing the first or second strip;
a cutting unit comprising a replaceable blade to partial-cut at least a portion of the first strip fixed to the chuck table; and
a cleaning unit for cleaning a surface or another surface of the cut second strip.

8. The semiconductor package cutting system of claim 7, wherein the cutting device further comprises a strip picker for moving the strip positioned on one of the chuck table, the cutting unit, the cleaning unit, and the rails to another.

9. The semiconductor package cutting system of claim 8, wherein the strip picker is movable back and forth in the second direction at a position corresponding to the rails.

10. A semiconductor package cutting method comprising:
(a) moving a strip supplied from a storage device and placed on rails of an inspection device, to a cutting device by moving a strip picker of the cutting device;
(b) partial-cutting at least a portion of the strip by using the cutting device;
(c) moving the cut strip to the inspection device and inspecting a cut depth; and
(d) moving and storing the inspected strip to and in the storage device.
